(19) United States
(12) Patent Application Publication
(10) Pub. No.: US 2005/0134253 A1
(43) Pub. Date: Jun. 23, 2005

(54) Current sensor

(76) Inventors: Thomas E. Kovanko, Chicago, IL (US); Michael G. Ennis, Evanston, IL (US); Jeffrey A. Moore, Lake Zurich, IL (US); Debashis Satpathi, San Fe, NM (US)

Correspondence Address: James V. Lapacek;S & C Electric Co., 6601 N. Ridge Blvd., Chicago, IL, 60626, US

(21) Appl. No.: 10/813,979

(22) Filed: Mar. 29, 2004

Related U.S. Application Data
(60) Provisional application No. 60/461,924, filed on Apr. 10, 2003.

(51) Int. Cl. G01R 31/00

(52) U.S. Cl. 324/96

(57) ABSTRACT

A magneto-striction based, passive optical current sensor is provided that is located at high voltage and communicates to ground level via an optical fiber. The optical current sensor includes a ferromagnetic core, a modulator of magnetostrictive material, e.g. Terfenol-D in a preferred embodiment, that responds to the magnetic field, and two or more matched fiber Bragg gratings that convert this response into a wavelength modulated optical signal that is transmitted via an optical fiber to ground level electronics. To linearize the output of the optical current sensor, the optical sensor includes arrangements to provide both mechanical and magnetic bias to the modulator.

This application claims the benefit of U.S. Provisional Application No. 60/461,924 filed on Apr. 10, 2003.

### BACKGROUND OF THE INVENTION

1. Field of the Invention

The present invention relates generally to the field of current sensing devices and more particularly to an improved magneto-striction based, passive optical current sensor that is located at high voltage and communicates to ground level via an optical fiber.

2. Description of Related Art

Various current sensors are known including iron-cored transformers commonly referred to as CT's. Additionally, optical current sensors are also known that utilize the Faraday magneto-optic effect.

While the prior art arrangements may be generally useful as current sensors, it is desirable to provide a current sensor of minimal size and with improved operating parameters.

### SUMMARY OF THE INVENTION

Accordingly, it is a principal object of the present invention to provide an improved magneto-striction based, passive optical current sensor that is located at high voltage and communicates to ground level via an optical fiber.

These and other objects of the present invention are efficiently achieved by a magneto-striction based, passive optical current sensor that is located at high voltage and communicates to ground level via an optical fiber. The optical current sensor includes a ferromagnetic core, a modulator of magnetostrictive material, e.g. Terfenol-D in a preferred embodiment, that responds to the magnetic field, and two or more matched fiber Bragg gratings that convert this response into a wavelength modulated optical signal that is transmitted via an optical fiber to ground level electronics. To linearize the output of the optical current sensor, the optical sensor includes arrangements to provide both mechanical and magnetic bias to the modulator.

### BRIEF DESCRIPTION OF THE DRAWING

The invention, both as to its organization and method of operation, together with further objects and advantages thereof, will best be understood by reference to the specification taken in conjunction with the accompanying drawing in which:

FIG. 1 is a schematic and diagrammatic representation of a current sensor in accordance with the present invention;

FIGS. 2a and 2b are respective plots of magnetic field versus magnetostrictive strain for no bias and with bias respectively of the current sensor of FIG. 1;

FIG. 3 is a plot of transmittance versus wavelength of the current sensor of FIG. 1;

FIG. 4 is an elevational view, partly in section, of an illustrative embodiment of a current sensor of the present invention in accordance with FIG. 1;

FIG. 5 is a plot of output current as measured by the current sensor of FIGS. 1 and 4 versus the measured conductor current;

FIG. 6 is a plot of the output of the current sensor of FIG. 4 and the conductor input current versus time; and

FIG. 7 is an elevational view, partly in section, of another embodiment of a current sensor in accordance with the present invention.

### DETAILED DESCRIPTION

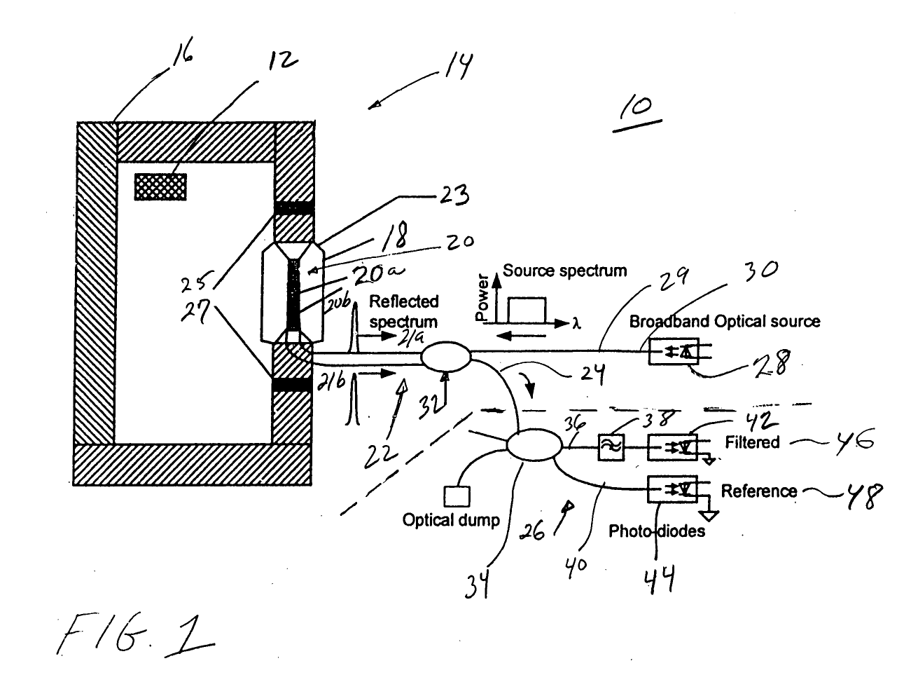

Referring now to FIG. 1, a current sensor 10 in accordance with the present invention is illustrated to function as a magneto-striction based, passive optical current sensing device for high voltage applications, e.g. to sense the current in a conductor 12. The current sensor 10 includes a sensor head 14 having a ferromagnetic core 16 in the shape of a yoke, a modulator 18 of magnetostrictive material, e.g. Terfenol-D in a preferred embodiment, that responds to the magnetic field generated by the current in the conductor 12, and one or more tunable fiber optical filters at 20, e.g. Bragg gratings, that convert this response into a wavelength modulated optical signal at 22 that is transmitted via an optical fiber 24 to ground level electronics at 26. For example, two tunable fiber optical filters 20a and 20b are illustrated in the illustrative embodiment of FIG. 1 although it should be realized that the number of tunable fiber optical filters 20 may be one or several in various other embodiments. A broad-band optical source 28 is used over path 30 and through a coupler at 32 to interrogate the tunable optical filters at 20, e.g. the output 29 of the optical source 28 being distributed equally between the two illustrated tunable fiber optical filters at 20 by the coupler at 32. The tunable fiber optical filters 20a and 20b reflect back a narrow characteristic spectrum at 21a, 21b respectively, e.g. with a center frequency determined by the pitch of the grating that changes in response to applied strain. The reflected spectrum travels down the same path used to illuminate the tunable fiber optical filters 20a and 20b. Accordingly, the modulator 18 and the tunable fiber optical filters 20a and 20b in combination produce a spectral output that is proportional to the current in the conductor 12 in the form of a wavelength-modulated output at 24, i.e. picking up the strain generated by the modulator 18 by the magnetic field of the conductor 12 and transmitting the information as a reflected wavelength modulated signal back at 21a, 21b.

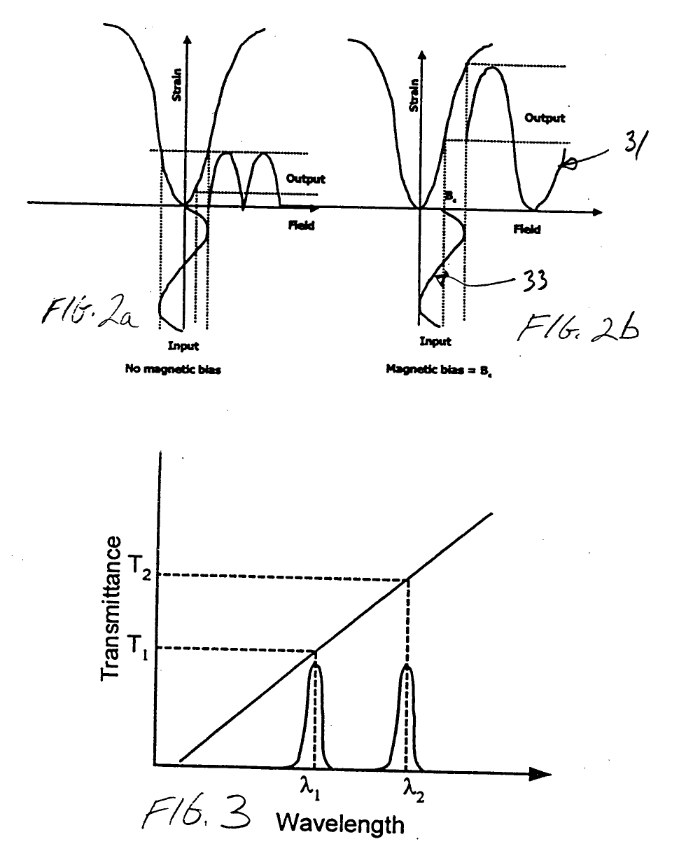

In accordance with important aspects of the present invention and referring now additionally to FIG. 2, it is useful to bias the operating point of the of the strain versus magnetic field characteristic of the modulator 18 to achieve a linearization of the strain output 31 versus the magnetic field input 33. Specifically, it has been found useful to utilize both dc magnetic bias, e.g. via the permanent magnets at 25, 27 in the core 16, and mechanical prestress of the modulator 18 as shown at 23 in FIG. 1 and as will be explained in more detail hereinafter. FIG. 2a illustrates this relationship without magnetic bias and FIG. 2b illustrates the linearization achieved with magnetic bias so as to produce a strain output at 31 that is proportional to the magnetic field strength in the modulator 18. This has also been found to reduce hysteresis and prevent the modulator 18 from having excessive tension applied thereto.

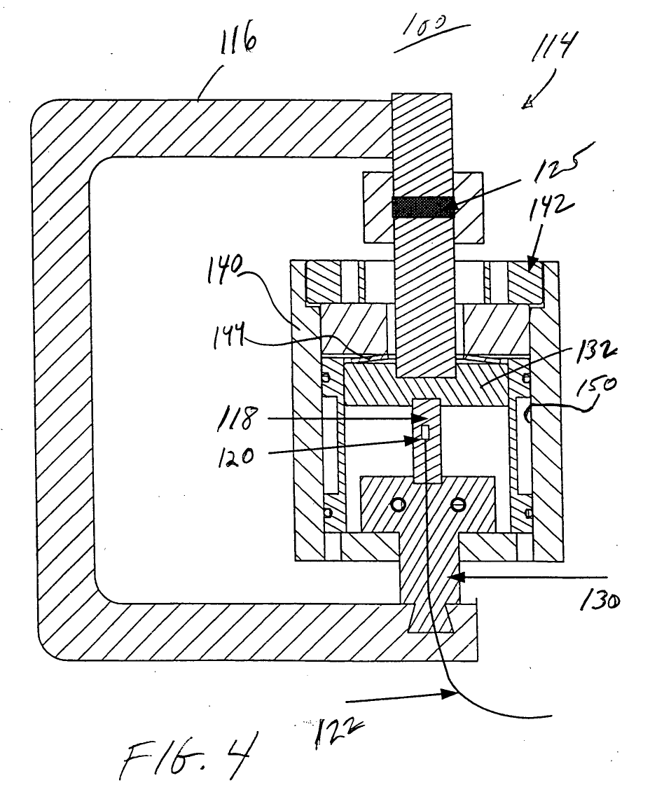

In the illustrative embodiment, the reflected signals at 24 are split into two paths via a second coupler 34 of the ground level electronics at 26. A first path 36 out of the coupler is connected through a linear transmission filter 38 having a transmittance that varies linearly with wavelength as illustrated in FIG. 3 so as to function as a passive wavelength demodulator, i.e. since the transmittance of the linear transmission filter 38 varies linearly with wavelength, any changes in the reflected spectrum at 36 with respect to wavelength results in a change in the transmitted intensity at the output of the filter 38. The output of the filter 38 and the second path from the second coupler 34 are each to respective photodiode arrangements 42 and 44 so as to produce at respective output signals at 46, 48 that are have a voltage proportional to the input intensity of the light to the respective photodiode arrangements 42, 44. Accordingly, any changes in intensity to the photodiode arrangement 42 is translated into a proportional change in the voltage output at 46. The reference path and output at 48 is useful to stabilize the sensor 10 against intensity variations produced by drift in the optical source 28 or other environmental effects, e.g. by normalizing the output at 46 by the output at 48. In this way, it has been found that the output at 46 linearly tracks the current in the conductor 12 within the limits of the linearity of the modulator 18 and the optics of the sensor 10. It should also be noted that the use of two or more tunable fiber optical filters, e.g. 20a and 20b, not only provides more accurate pickup of the strain of the modulator 18 via area coverage but also improves the signal to noise ratio of the signal at 46. This is achieved via the presence of the two reflected signals and also via the further reflection of each reflected signal through the other tunable fiber optical filter. The sensor 10 in one arrangement was found to have a useful linear range of 200-1000 amperes in response to 60 Hz current in the conductor 12. It should also be noted that the optical fiber path at 24 is the only path traversing the high voltage barrier or area of the sensor head 14 and the ground-level electronics at 26, thus reducing insulation requirements. It should also be noted that the wavelength demodulation arrangement shown and discussed is illustrative only since various other methods are also possible in particular applications.

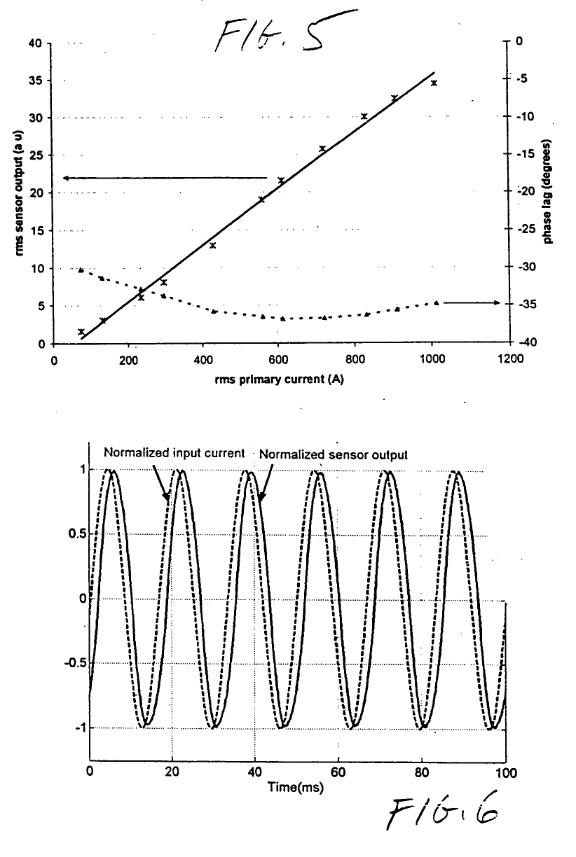

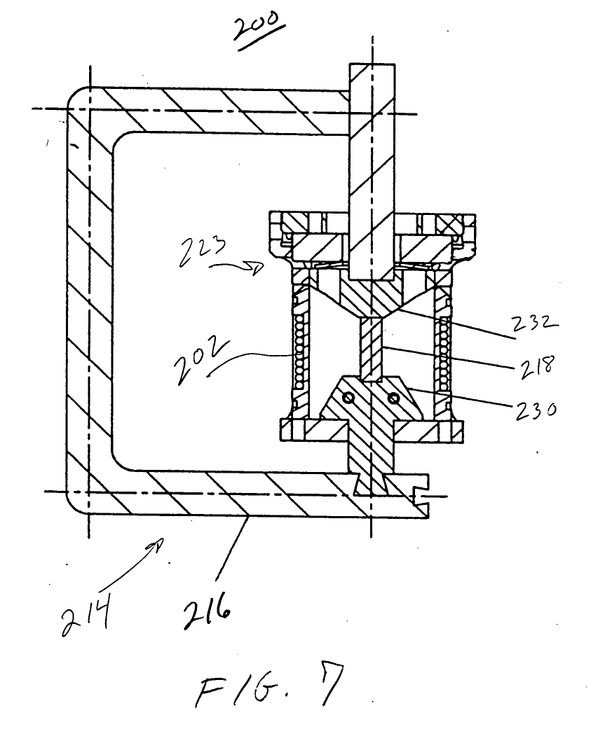

With additional reference now to FIGS. 4-6, an illustrative embodiment of a current sensor 100 in accordance with the principles of the present invention and the current sensor 10 of FIGS. 1-3 illustrates specific structure and configuration of a sensor head 114, e.g. for use in the current sensor 10 of FIG. 1. The modulator 118 with one or more attached tunable fiber optical filters at 120 is positioned between two pole pieces 130, 132. The pole pieces 130, 132 are attached to the core 116. A cylindrical shell 140 is utilized in combination with a locknut assembly at 142 to provide mechanical prestress to the modulator 118, i.e. mechanical strain to perform a bias function as discussed hereinbefore. In a specific arrangement, a Beliville-type washer 144 is utilized to apply this prestress to the pole pieces 130, 132 within the cylindrical shell 140, e.g. the Beliville-type washer 144 being deformed to produce the desired force and then maintaining this deformation via the locknut assembly 142. A permanent magnet 125 provides the desired magnetic bias to the sensor head 114. The output of the tunable optical filters at 120 is via an optical fiber at 122. The annular space at 150 in the cylindrical shell 140 is utilized in specific embodiments for a DC bias coil (not shown here but illustrated in the arrangement of FIG. 7) either in lieu of or in addition to the magnet 125. FIG. 5 illustrates the rms magnitude and phase response at the output 124 of the current sensor 100 in response to 60 Hz currents in the range of 50-1000 amperes. Additionally, FIG. 6 illustrates the linear response of the current sensor 100 to 60 Hz input current, e.g. current in the conductor 12 as shown in FIG. 1.

Another illustrative embodiment of a current sensor 200 in accordance with the present invention is shown in FIG. 7 wherein a DC bias coil 202 is provided in the sensor head 214 in lieu of magnets in the core 216 to provide the magnetic bias. A mechanical prestress arrangement 223 is shown that is similar to that of FIG. 4. In the current sensor 200, the modulator 218 is held and strained between pole pieces 230 and 232 that are shaped to provide desired flux concentrations to the modulator 218.

While there have been illustrated and described various embodiments of the present invention, it will be apparent that various changes and modifications will occur to those skilled in the art. Accordingly, it is intended in the appended claims to cover all such changes and modifications that fall within the true spirit and scope of the present invention.

1. An optical current sensor for responding to a current in a conductor comprising:
a modulator having magneto-strictive properties;
first means affixed to said modulator for providing an output proportional to the current in the conductor; and
second means for coupling the magnetic field generated by the current in the conductor to said modulator and linearizing the output of said first means by providing both DC magnetic bias and mechanical prestress bias to said modulator.

2. The optical current sensor of claim 1 wherein said first means includes two or more tunable fiber optical filters and the output of said first means is formed by contribution from each of said tunable fiber optical filters.

3. The optical current sensor of claim 1 wherein said second means defines a magnetic path and includes a permanent magnet arranged in said magnetic path.
